(19) United States
(12) Patent Application Publication
(10) Pub. No.: US 2023/0059168 A1
(43) Pub. Date: Feb. 23, 2023

(54) FILM FORMATION APPARATUS AND METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); NATIONAL UNIVERSITY CORPORATION KYOTO INSTITUTE OF TECHNOLOGY, Kyoto-shi (JP)

(72) Inventors: Tatsuji NAGAOKA, Nisshin-shi (JP); Hiroyuki NISHINAKA, Kyoto-shi (JP); Masahiro YOSHIMOTO, Kyoto-shi (JP)

(21) Appl. No.: 17/886,986

(22) Filed: Aug. 12, 2022

(30) Foreign Application Priority Data
Aug. 17, 2021 (JP) 2021-132611

(51) Int. Cl. C30B 25/14; C30B 25/10; C30B 25/20; C30B 29/16; C23C 16/40; C23C 16/448; C23C 16/46; H01L 21/02

(52) U.S. Cl. CPC C30B 25/14; C30B 25/10; C30B 25/20; C30B 29/16; C23C 16/40; C23C 16/4486; C23C 16/46; H01L 21/02565; H01L 21/02579; H01L 21/02598; H01L 21/0262; H01L 21/02634; H01L 21/02414

(57) ABSTRACT

A film formation apparatus includes a stage, a heater, a mist supply source, a superheated vapor supply source, and a delivery device. The stage is configured to allow a substrate to be mounted thereon. The heater is configured to heat the substrate. The mist supply source is configured to supply mist of a solution that comprises solvent and a film material dissolved in the solvent. The superheated vapor supply source is configured to supply a superheated vapor of a same material as the solvent. The delivery device is configured to deliver the mist and the superheated vapor toward a surface of the substrate to grow a film containing the film material on the surface of the substrate.

### CROSS REFERENCE TO RELATED APPLICATION

The present application claims the benefit of priority from Japanese Patent Application No. 2021-132611 filed on Aug. 17, 2021. The entire disclosures of the above application are incorporated herein by reference.

### TECHNICAL FIELD

The technique disclosed herein relates to a film formation apparatus and a method for manufacturing a semiconductor device.

### BACKGROUND

It has been proposed a film formation apparatus configured to grow a film on a surface of a substrate. The film formation apparatus supplies mist of a solution that includes a solvent and a material of the film dissolved in the solvent, and heated gas to the surface of the substrate, so the film is grown on the surface of the substrate.

### SUMMARY

The present disclosure describes a film formation apparatus, which is capable of heating mist more efficiently, and a method for manufacturing a semiconductor device using the film formation apparatus.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a configuration diagram of a film formation apparatus according to a first embodiment;

FIG. 2 is a graph showing the relationship between the temperature T of a gas, a mass velocity G of a gas, and an evaporation rate S of water;

FIG. 3 is a configuration diagram of a film formation apparatus according to a modified example;

FIG. 4 is a configuration diagram of a film formation apparatus according to a second embodiment; and

FIG. 5 is a configuration diagram of a film formation apparatus according to a third embodiment.

### DETAILED DESCRIPTION

To begin with, a relevant technology will be described only for understanding the embodiments of the present disclosure.

It has been proposed a film formation apparatus configured to grow a film on a surface of a substrate. The film formation apparatus supplies mist of a solution that includes a solvent and a material of the film dissolved in the solvent, and heated gas to the surface of the substrate, so the film is grown on the surface of the substrate. In such a configuration, the mist can be heated by the heated gas while suppressing evaporation of the solvent from the mist. Since the heated mist is supplied to the surface of the substrate, the temperature drop of the substrate can be suppressed. Accordingly, the film can be epitaxially grown on the surface of the substrate with stable quality.

In such a technique, however, a heating efficiency of the mist by the heated gas may not be so high. The present disclosure provides a technique which is capable of heating the mist more efficiently.

According to an aspect of the present disclosure, a film formation apparatus may include: a stage configured to allow a substrate to be mounted thereon; a heater configured to heat the substrate; a mist supply source configured to supply mist of a solution that includes a solvent and a film material dissolved in the solvent; a superheated vapor supply source configured to supply a superheated vapor of a same material as the solvent; and a delivery device configured to deliver the mist and the superheated vapor toward the surface of the substrate to grow a film containing the film material on the surface of the substrate.

The superheated vapor means a gas having a temperature higher than a boiling point.

In such a film formation apparatus, the mist and the superheated vapor are delivered toward the surface of the substrate. When the mist and the superheated vapor are delivered toward the surface of the substrate, the mist is heated by the superheated vapor. The molecular energy of the superheated vapor is much higher than that of saturated vapor (i.e., a gas having a temperature equal to the boiling point) because the energy of latent heat is required to raise the temperature of vapor to be higher than the temperature of the boiling point. Therefore, the mist can be more efficiently heated by means of the superheated vapor than the saturated vapor. That is, the mist can be efficiently heated by the superheated vapor while suppressing the evaporation of the solvent from the mist. Accordingly, the film formation apparatus described above enables the film to be grown on the surface of the substrate with more stable quality.

According to an aspect of the present disclosure, a method for manufacturing a semiconductor device is for manufacturing a semiconductor device using a film formation apparatus. The film formation apparatus: includes a stage configured to allow a substrate to be mounted thereon; a heater configured to heat the substrate; a mist supply source configured to supply mist of a solution that includes a solvent and a film material dissolved in the solvent; a superheated vapor supply source configured to supply a superheated vapor of a same material as the solvent; and a delivery device configured to deliver the mist and the superheated vapor toward the surface of the substrate. The method includes delivering the mist and the superheated vapor toward the surface of the substrate to grow a film containing the film material on the surface of the substrate.

According to the manufacturing method described above, the film can be grown on the surface of the substrate with more stable quality.

According to an aspect of the present disclosure, a film formation apparatus may be configured to epitaxially grow the film on the surface of the substrate.

According to an aspect of the present disclosure, in the film formation apparatus, the solvent may be H₂O and the superheated vapor may be a superheated water vapor.

According to an aspect of the present disclosure, in the film formation apparatus, the superheated water vapor may have a mass velocity G and a temperature T that satisfy a relation of T<530G^{-0.15} at a confluence position where the superheated water vapor and the mist are merged.

According to such a configuration, the heating efficiency of the mist by the superheated water vapor can be further increased.

According to an aspect of the present disclosure, in the film formation apparatus, the temperature of the superheated water vapor may be lower than 175 degrees Celsius (° C.).

According to an aspect of the present disclosure, in the film formation apparatus, the temperature of the superheated water vapor may be lower than 150° C.

According to an aspect of the present disclosure, in the film formation apparatus, a pressure in a flow path through which the superheated water vapor flows may be lower than the atmospheric pressure, and the temperature of the superheated water vapor may be lower than 100° C.

As described above, when the pressure in the flow path is lower than the atmospheric pressure, the boiling point of water is lower than 100° C., so that the temperature of the superheated water vapor can be lower than 100° C.

According to an aspect of the present disclosure, the delivery device may have a mixing flow path that allows a mixture of the mist and the superheated vapor to flow. The mixture may be delivered to the surface of the substrate through the mixing flow path.

In an embodiment of the present disclosure, the delivery device may have a first flow path and a second flow path provided separately from the first flow path. The mist may be delivered to the surface of the substrate through the first flow path. The superheated vapor may be delivered to the surface of the substrate through the second flow path.

According to an aspect of the present disclosure, in the film formation apparatus, the superheated vapor source may be configured to generate the superheated vapor by heating a liquid material made of the same material as the solvent to a first temperature lower than the boiling point of the liquid material, and then lowering the boiling point of the liquid material to the temperature lower than the first temperature by reducing the pressure of the liquid material.

According to such a configuration, a large amount of superheated vapor can be generated in a short time.

Embodiments of the present disclosure will be described more in detail with reference to the drawings.

### First Embodiment

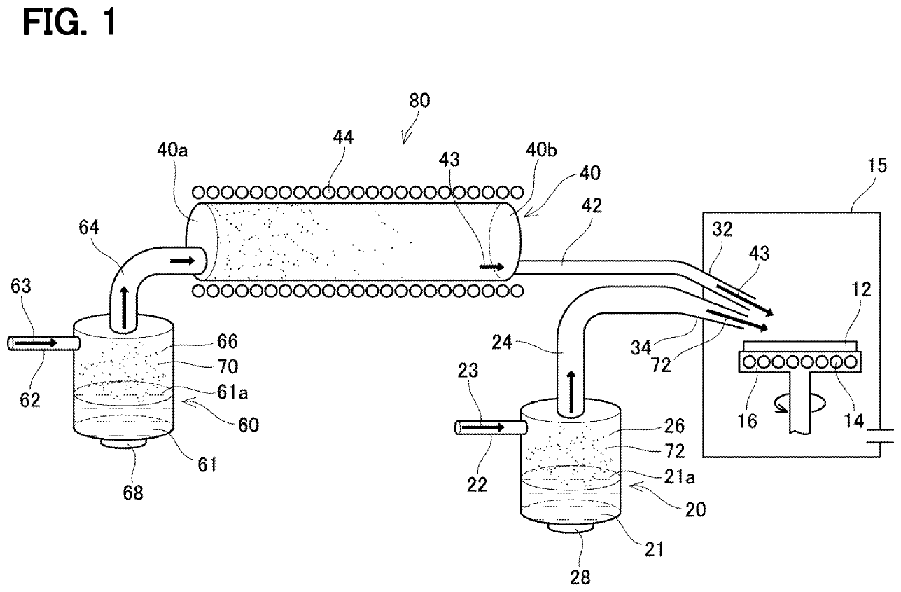

As shown in FIG. 1, a film formation apparatus of a first embodiment is configured to epitaxially grow a film on a surface of a substrate 12. The film formation apparatus of the first embodiment is used for manufacturing a semiconductor device having an epitaxially grown film. The film formation apparatus of the first embodiment includes a film formation furnace 15, a mist generation reservoir 20, and a superheated water vapor generator 80.

A susceptor 16 is arranged in the film formation furnace 15. The susceptor 16 has a horizontally arranged flat top surface. The susceptor 16 is configured to allow the substrate 12 to be mounted thereon. The susceptor 16 incorporates a heater 14 therein. The heater 14 heats the substrate 12. The susceptor 16 is rotatable about its central axis. As the susceptor 16 rotates, the substrate 12 on the susceptor 16 rotates within the plane.

The mist generation reservoir 20 is a closed container. The mist generation reservoir 20 is configured to store a solution 21 in which a raw material of the film to be epitaxially grown on the surface of the substrate 12 is dissolved in water (H₂O). For example, in the case of epitaxially growing a film of gallium oxide (Ga₂O₃), a solution in which gallium is dissolved in water can be used as the solution 21. For example, a raw material (for example, ammonium fluoride or the like) for imparting an n-type or p-type dopant to the gallium oxide film may be further dissolved in the solution 21. For example, hydrochloric acid may be contained in the solution 21. In the mist generation reservoir 20, a space 26 is provided between a surface 21a of the solution 21 and an upper surface of the mist generation reservoir 20. An ultrasonic vibrator 28 is installed at a bottom surface of the mist generation reservoir 20. The ultrasonic vibrator 28 is configured to apply ultrasonic waves to the solution 21 stored in the mist generation reservoir 20. When the ultrasonic waves are applied to the solution 21, the surface 21a of the solution 21 vibrates, and a mist of the solution 21 (hereinafter referred to as a solution mist 72) is generated in the space 26 above the solution 21. An upstream end of a solution mist supply path 24 is connected to the upper surface of the mist generation reservoir 20. A downstream end of a carrier gas supply path 22 is connected to an upper part of an outer peripheral wall of the mist generation reservoir 20. An upstream end of the carrier gas supply path 22 is connected to a carrier gas supply source (not shown). The carrier gas supply path 22 is configured to introduce a carrier gas 23 from the carrier gas supply source into the space 26 in the mist generation reservoir 20. The carrier gas 23 is, for example, an inert gas such as nitrogen. The carrier gas 23 that has been introduced into the space 26 from the carrier gas supply path 22 flows from the space 26 to the solution mist supply path 24. At this time, a solution mist 72 in the space 26 flows to the solution mist supply path 24 together with the carrier gas 23.

The solution mist supply path 24 extends to the inside of the film formation furnace 15. A downstream end of the solution mist supply path 24 is formed with a nozzle 34 extending toward the upper surface of the susceptor 16. The solution mist 72 that has flowed to the downstream end of the solution mist supply path 24 is discharged from the nozzle 34 toward the upper surface of the substrate 12 on the susceptor 16.

The superheated water vapor generator 80 has a water storage reservoir 60 and a heating furnace 40.

The water storage reservoir 60 is a closed container. The water storage reservoir 60 stores water, more specifically, pure water (H₂O) 61. A space 66 is provided between a surface 61a of the water 61 and an upper surface of the water storage reservoir 60. An ultrasonic vibrator 68 is installed at a bottom surface of the water storage reservoir 60. The ultrasonic vibrator 68 is configured to apply ultrasonic waves to the water 61 stored in the water storage reservoir 60. When ultrasonic waves are applied to the water 61, the surface 61a of the water 61 vibrates, and mist of the water 61 (hereinafter referred to as water mist 70) is generated in the space 66 above the water 61. An upstream end of the water mist supply path 64 is connected to the upper surface of the water storage reservoir 60. A downstream end of a carrier gas supply path 62 is connected to an upper part of an outer peripheral wall of the water storage reservoir 60. An upstream end of the carrier gas supply path 62 is connected to a carrier gas supply source (not shown). The carrier gas supply path 62 is configured to introduce a carrier gas 63 from the carrier gas supply source into the space 66 in the water storage reservoir 60. The carrier gas 63 is, for example, an inert gas such as nitrogen. The carrier gas 63 that has been introduced into the space 66 from the carrier gas supply path 62 flows from the space 66 into the water mist supply path 64. At this time, the water mist 70 in the space 66 flows to the water mist supply path 64 together with the carrier gas 63.

The heating furnace 40 is a tubular furnace extending from an upstream end 40a to a downstream end 40b. A heater 44 is arranged outside the heating furnace 40. The heater 44 is a heating wire type heater and is arranged along an outer peripheral wall of the heating furnace 40. The heater 44 heats the outer peripheral wall of the heating furnace 40, thereby heating an inside of the heating furnace 40. A downstream end of the water mist supply path 64 is connected to the upstream end 40a of the heating furnace 40. An upstream end of the superheated water vapor supply path 42 is connected to the downstream end 40b of the heating furnace 40. The water mist 70 and the carrier gas 63 are introduced into the heating furnace 40 from the water mist supply path 64. The water mist 70 and the carrier gas 63 flow through the heating furnace 40 from the upstream end 40a to the downstream end 40b. The water mist 70 and the carrier gas 63 are heated inside the heating furnace 40. While flowing through the heating furnace 40, the water mist 70 evaporates, and turns into water vapor. The pressure inside a flow path through which the water vapor generated in the heating furnace 40 flows, that is, the pressure inside the heating furnace 40, the superheated water vapor supply path 42, and the film formation furnace 15 is substantially atmospheric pressure. In the heating furnace 40, the water vapor is heated to a temperature higher than 100° C., that is, the boiling point of water under atmospheric pressure. Therefore, a superheated water vapor 43 is generated in the heating furnace 40. The superheated water vapor 43 flows from the heating furnace 40 into the superheated water vapor supply path 42. The superheated water vapor 43 is a superheated vapor made of the same material as water (H₂O), which is the solvent of the solution 21.

The superheated water vapor supply path 42 extends to the inside of the film formation furnace 15. A downstream end of the superheated water vapor supply path 42 is formed with a nozzle 32 extending toward the upper surface of the susceptor 16. The superheated water vapor 43 that has flowed to the downstream end of the superheated water vapor supply path 42 is discharged from the nozzle 32 toward the upper surface of the substrate 12 on the susceptor 16.

Next, a film formation method using the film formation apparatus of the first embodiment will be described. Here, a semiconductor substrate that is composed of a single crystal of p-type gallium oxide (β-Ga₂O₃) is used as the substrate 12. Further, an aqueous solution that contains water and gallium chloride (GaCl₃, Ga₂Cl₆) dissolved in the water is used as the solution 21. Moreover, nitrogen gas is used as the carrier gas 23 and 63.

First, the substrate 12 is installed on the susceptor 16. Next, the substrate 12 is heated by the heater 14 while rotating the susceptor 16. When the temperature of the substrate 12 has stabilized, the ultrasonic vibrator 68 is activated so as to generate the water mist 70 in the space 66 of the water storage reservoir 60. Further, the carrier gas 63 is introduced from the carrier gas supply path 62 into the water storage reservoir 60. The water mist 70 thus flows into the heating furnace 40 through the water mist supply path 64, and the superheated water vapor 43 is generated in the heating furnace 40. The superheated water vapor 43 flows into the nozzle 32 through the superheated water vapor supply path 42. As such, the superheated water vapor 43 is discharged from the nozzle 32 toward the upper surface of the substrate 12. Further, the ultrasonic vibrator 28 is activated substantially at the same time as the ultrasonic vibrator 68 is activated. As a result, the solution mist 72 is generated in the space 26 of the mist generation reservoir 20. Further, the carrier gas 23 is introduced from the carrier gas supply path 22 into the mist generation reservoir 20. The solution mist 72 thus flows into the nozzle 34 through the solution mist supply path 24. As such, the solution mist 72 is discharged from the nozzle 34 toward the upper surface of the substrate 12.

The superheated water vapor 43 discharged from the nozzle 32 and the solution mist 72 discharged from the nozzle 34 merge together above the substrate 12. The nozzle 32 and the nozzle 34 are configured such that an angle between a discharge direction of the nozzle 32 and a discharge direction of the nozzle 34 is less than 90°. Therefore, a relative velocity Vr of the superheated water vapor 43 and the solution mist 72 at a confluence position is lower than a flow velocity V₄₃ of the superheated water vapor 43 discharged from the nozzle 32. The superheated water vapor 43 and the solution mist 72 are mixed at a position above the substrate 12. Thus, a mixture of the superheated water vapor 43 and solution mist 72 is supplied to the upper surface of the substrate 12.

When the superheated water vapor 43 and the solution mist 72 are mixed, the solution mist 72 is heated by the superheated water vapor 43. Since the superheated water vapor 43 has high energy, the solution mist 72 can be efficiently heated.

When the mixture of the superheated water vapor 43 and the solution mist 72 is discharged toward the upper surface of the substrate 12, the solution mist 72 adheres to the upper surface of the substrate 12. Because the temperature of the substrate 12 is higher than the temperature of the solution mist 72, the solution mist 72 (that is, the solution 21) causes a chemical reaction on the substrate 12. As a result, β-type gallium oxide (β-Ga₂O₃) is generated on the substrate 12. Because the solution mist 72 is continuously supplied to the surface of the substrate 12, a gallium oxide film grows on the upper surface of the substrate 12. A single crystal gallium oxide film epitaxially grows on the surface of the substrate 12. A semiconductor device can be manufactured by using the gallium oxide film thus formed. In a case where the solution 21 contains a raw material for the dopant, the dopant is incorporated into the gallium oxide film. For example, in a case where the solution 21 contains ammonium fluoride (NH₄F), a gallium oxide film doped with fluoride is formed.

When adhering to the upper surface of the substrate 12, the solution mist 72 removes heat from the substrate 12. At this time, if the temperature of the substrate 12 decreases, the film quality of a gallium oxide film is likely to deteriorate. In the first embodiment, on the other hand, since the solution mist 72 has been heated by the superheated water vapor 43, it is less likely that the solution mist 72 will remove heat from the substrate 12 when the solution mist 72 adheres to the upper surface of the substrate 12. Therefore, the substrate 12 can be stably maintained at an appropriate temperature. As a result, the gallium oxide film can be suitably grown epitaxially on the upper surface of the substrate 12.

When the water, that is, the solvent evaporates from the solution mist 72 during heating of the solution mist 72, the concentration of the solution 21 constituting each droplet of the solution mist 72 increases. If the concentration of the solution 21 constituting each droplet changes as described above, it becomes difficult to control the characteristics of the film to be grown. Further, if the water excessively evaporates from the solution 21 constituting each droplet, the solution 21 changes into solid fine particles. If such solid fine particles are generated, the solid fine particles adhere to the film to be grown and the film quality is likely to deteriorate. However, in the film formation apparatus of the present embodiment, since the solution mist 72 is heated by the superheated water vapor 43, the partial pressure of the water vapor is high around the solution mist 72, and it is less likely that the water will evaporate from the solution mist 72. Therefore, the solution 21 having an appropriate concentration can be supplied to the upper surface of the substrate 12 as the solution mist 72. As a result, a high-quality film can be grown on the upper surface of the substrate 12.

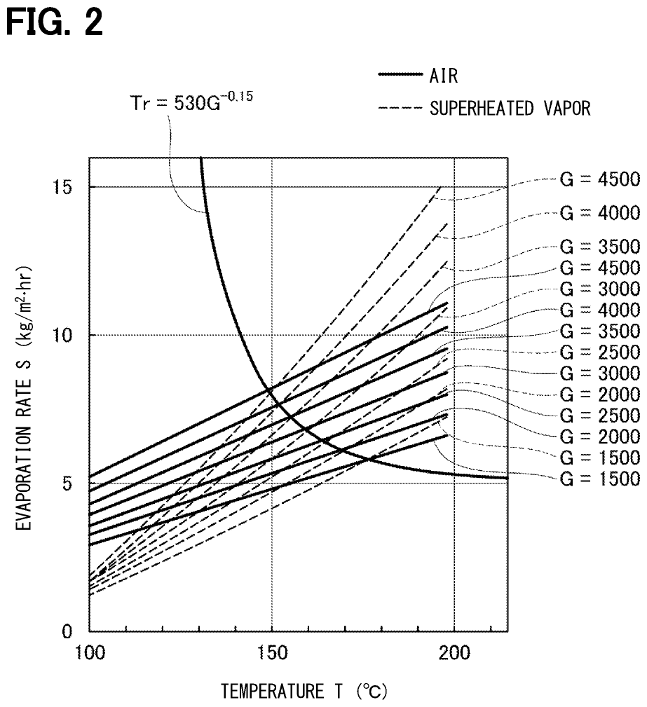

When water is heated by a gas, an evaporation rate S (kg/(m²·hr)) of water is different depending on the type of gas, a mass velocity G (kg/(m²·hr)) of the gas, and the temperature T (° C.) of the gas. The mass velocity G is the mass of the gas flowing per unit time when the gas is applied toward the water. FIG. 2 shows the evaporation rate S of the water when the water in a stationary state is heated by a gas (air or superheated water vapor). As shown in FIG. 2, the evaporation rate S of air and the evaporation rate S of the superheated water vapor increase with an increase in the mass velocity G. Further, the evaporation rate S of each mass velocity G increases with an increase in the temperature T. A rate of increase in the evaporation rate S of each mass velocity G with respect to the temperature T (that is, the slope of the graph) is larger in the superheated water vapor than in the air. Therefore, in each mass velocity G, there is a reversal point temperature Tr in which the magnitude of the evaporation rate S is reversed between the superheated water vapor and the air. That is, in regard to each mass velocity G, when the temperature T is lower than the reversal point temperature Tr, the evaporation rate S of the superheated water vapor is smaller than that of the air, and when the temperature T is higher than the reversal point temperature Tr, the evaporation rate S of the superheated water vapor is higher than the air. Therefore, in the case where the water is heated by the superheated water vapor, if the temperature T of the superheated water vapor is lower than the reversal point temperature Tr, the water can be heated more efficiently. From the experimental results of FIG. 2, the reversal point temperature Tr can be regarded as a function of the mass velocity G. The reversal point temperature Tr satisfies a relation of Tr=530G^{-0.15}. Therefore, if the superheated water vapor is in the temperature range satisfying T<530G^{-0.15}, the water can be heated while effectively suppressing the evaporation of the water.

In the film formation apparatus of the first embodiment, a mass velocity G₄₃ and the temperature T₄₃ of the superheated water vapor 43 discharged from the nozzle 32 satisfy a relation of T₄₃<530G₄₃^{-0.15}. As described above, the relative velocity Vr of the superheated water vapor 43 and the solution mist 72 at the confluence position of the superheated water vapor 43 and the solution mist 72 is lower than the flow velocity V₄₃ of the superheated water vapor 43 discharged from the nozzle 32. Therefore, the mass velocity Gr of the superheated water vapor 43 with respect to the solution mist 72 at the confluence position is lower than the mass velocity G₄₃ of the superheated water vapor 43 discharged from the nozzle 32. As such, if the relation of T₄₃<530G₄₃^{-0.15} is satisfied, the relation of T₄₃<530Gr^{-0.15} is satisfied. In the film formation apparatus of the first embodiment, therefore, the temperature T₄₃ of the superheated water vapor 43 at the confluence position can be set to a temperature lower than the reversal point temperature Tr. Accordingly, in the film formation apparatus of the first embodiment, the solution mist 72 can be heated by the superheated water vapor 43 while effectively suppressing the evaporation of water from the solution mist 72. The temperature T₄₃ may be lower than 175° C. By setting the temperature T₄₃ to be lower than 175° C., the temperature T₄₃ can be set to be equal to or lower than the reversal point temperature within the range of a practical mass velocity Gr. In particular, the temperature T₄₃ may be lower than 150° C.

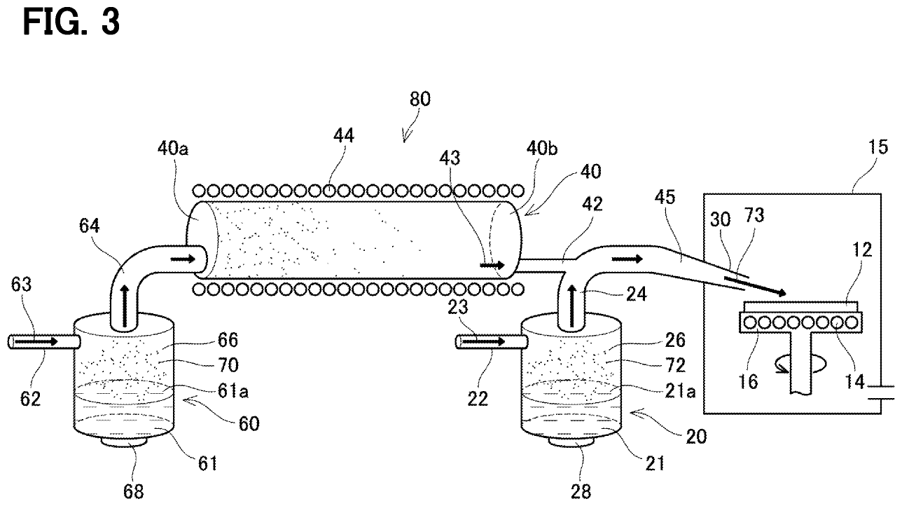

In the first embodiment, the superheated water vapor supply path 42 and the solution mist supply path 24 are separate. However, as shown in FIG. 3, the superheated water vapor supply path 42 and the solution mist supply path 24 may be merged at their downstream positions to form a mixing flow path 45. A downstream end of the mixing flow path 45 is formed with a nozzle 30 extending toward the upper surface of the substrate 12. In this configuration, the superheated water vapor 43 and the solution mist 72 merge at an upstream end of the mixing flow path 45. The superheated water vapor 43 and the solution mist 72 are mixed in the mixing flow path 45 to form a mixture 73. The mixture 73 is discharged from the nozzle 30 toward the upper surface of the substrate 12. Even in this configuration, the solution mist 72 can be heated by the superheated water vapor 43 while suppressing the evaporation of water from the solution mist 72. In this case, the temperature T₄₃ and the mass velocity G₄₃ of the superheated water vapor 43 are set so as to satisfy the relationship of T₄₃<530G₄₃^{-0.15} at the confluence position of the superheated water vapor 43 and the solution mist 72, that is, at the upstream end of the mixing flow path 45. As a result, the evaporation of water from the solution mist 72 can be suppressed more effectively.

### Second Embodiment

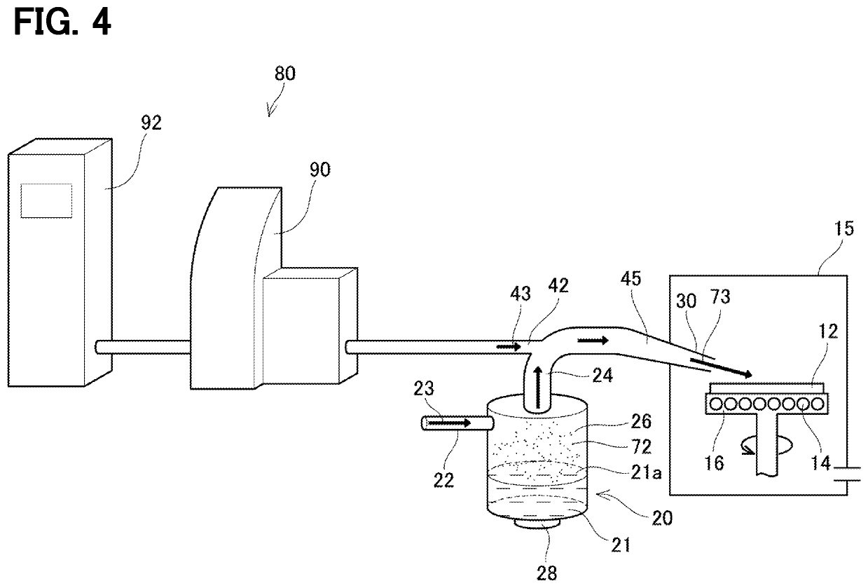

A second embodiment will be described with reference to FIG. 4. In a film formation apparatus of the second embodiment shown in FIG. 4, a superheated water vapor generator 80 includes a liquid material vaporization system 90 and a refill system 92. Other configurations of the film formation apparatus of the second embodiment are the same as those of the film formation apparatus of FIG. 3. The refill system 92 supplies water to the liquid material vaporization system 90. The liquid material vaporization system 90 sequentially executes a heat treatment and a pressure reduction treatment on the water supplied from the refill system 92. In the heat treatment, the liquid material vaporization system 90 heats the water under a pressure P1 higher than the atmospheric pressure. In this case, the liquid material vaporization system 90 heats the water to a temperature that is below the boiling point. In the pressure reduction treatment, the liquid material vaporization system 90 reduces the pressure applied to the water from the pressure P1 to a pressure P2. With this, the boiling point of the water drops to a temperature lower than the temperature of the water. That is, the water is brought into a state in which the temperature of the water is higher than the boiling point. As a result, the water evaporates rapidly and superheated water vapor 43 is generated.

For example, in the heat treatment, in a state where the water is applied with the pressure P1 at which the boiling point of water is about 130° C., the water can be heated to 120° C., which is higher than 100° C. and lower than the boiling point (that is, about 130° C.). After that, when the water is transferred under the pressure P2 which is substantially equal to the atmospheric pressure, the boiling point of the water drops to about 100° C. Thus, the temperature of the water (about 120° C.) is higher than the boiling point (about 100° C.), so that the water evaporates rapidly. As a result, the superheated water vapor 43 having a temperature higher than the boiling point (about 100° C.) is generated.

As described above, according to the method of lowering the boiling point of water by reducing the pressure, the superheated water vapor 43 can be generated more rapidly than the method of simply heating water.

The superheated water vapor 43 generated by the liquid material vaporization system 90 is sent to the mixing flow path 45 via the superheated water vapor supply path 42. Further, the solution mist 72 generated in the mist generation reservoir 20 is sent to the mixing flow path 45 via the solution mist supply path 24. In the mixing flow path 45, the superheated water vapor 43 and the solution mist 72 are mixed. A mixture 73 of the superheated water vapor 43 and the solution mist 72 is discharged from the nozzle 30 toward the upper surface of the substrate 12. Therefore, similarly to the film formation apparatus of FIG. 3, the film can be efficiently grown on the upper surface of the substrate 12.

In the configuration in which the superheated water vapor 43 and the solution mist 72 are mixed in the mixing flow path 45 as shown in FIG. 4, since the heating time of the solution mist 72 by the superheated water vapor 43 is long, the solution mist 72 can be uniformly heated. On the other hand, if the heating time is long, the water evaporates from the solution mist 72 and the concentration of the solution 21 constituting the solution mist 72 is likely to change. In the second embodiment, when the superheated water vapor 43 having a temperature lower than 150° C. is used, the number of water molecules that aggregate in the solution mist 72 and the number of water molecules that evaporate from the solution mist 72 are easily balanced. Therefore, the change in the concentration of the solution 21 constituting the solution mist 72 can be suppressed.

In the second embodiment, the superheated water vapor supply path 42 and the solution mist supply path 24 may be separated as in FIG. 1.

### Third Embodiment

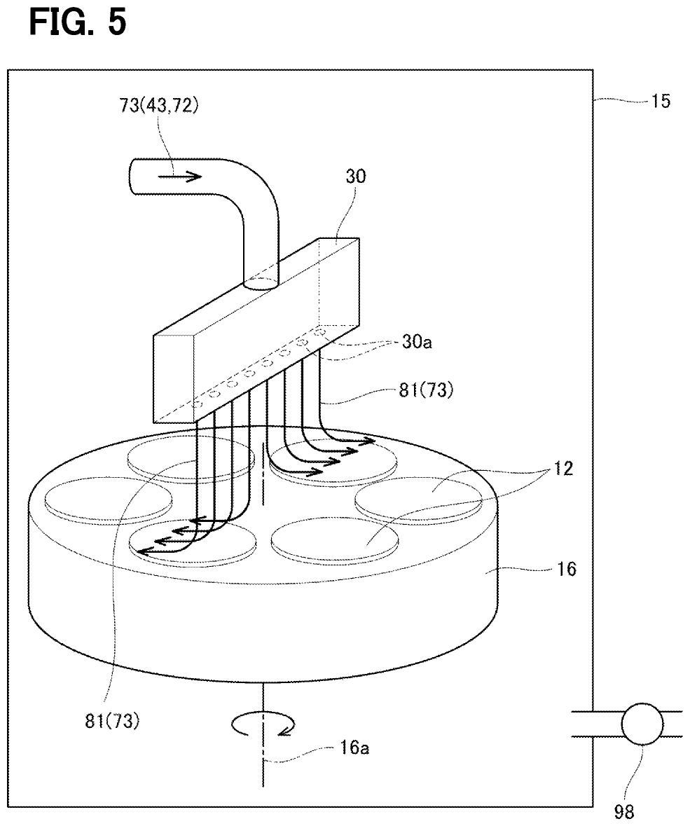

A third embodiment of the present disclosure will be described with reference to FIG. 5. As shown in FIG. 5, in a firm formation apparatus of the third embodiment, the mixture 73 of the superheated water vapor 43 and the solution mist 72 is supplied to the nozzle 30. The nozzle 30 has a rectangular parallelepiped shape that is elongated in one direction. The nozzle 30 has a plurality of discharge ports 30a on a lower surface. The discharge ports 30a are arranged in line. The nozzle 30 discharges the mixture 73 from each discharge port 30a toward the susceptor 16. Further, in the third embodiment, a plurality of substrates 12 can be placed on the susceptor 16. The substrates 12 are arranged around the central axis 16a of the susceptor 16. As shown by arrows 81, the mixture 73 discharged downward from the nozzle 30 is able to impinge on an entirety of a diameter of the susceptor 16. The susceptor 16 rotates around the central axis 16a. Further, in the third embodiment, an exhaust pump 98 is installed at an exhaust port of the film formation furnace 15. By activating the exhaust pump 98, the pressure inside the film formation furnace 15 is reduced. That is, in the third embodiment, the pressure inside the film formation furnace 15 is lower than the atmospheric pressure.

When the susceptor 16 is rotated while discharging the mixture 73 from the nozzle 30, the mixture 73 flows laminar along the upper surfaces of the substrates 12. Therefore, the gallium oxide film can be uniformly grown on the upper surface of each substrate 12.

Further, in the third embodiment, since the pressure in the film formation furnace 15 is lower than the atmospheric pressure, the boiling point of the water in the film formation furnace 15 is lower than 100° C. For example, the pressure in the film formation furnace 15 can be controlled so that the boiling point of water in the film formation furnace 15 is about 80° C. Moreover, in the third embodiment, the temperature of the superheated water vapor 43 supplied from the nozzle 30 into the film formation furnace 15 is higher than the boiling point of water in the film formation furnace 15 and lower than 100° C. For example, the temperature of the superheated water vapor 43 supplied into the film formation furnace 15 can be about 90° C. As described above, even the water vapor having the temperature lower than 100° C. can become superheated water vapor in a pressure-reduced atmosphere. Even in this configuration, the solution mist 72 can be heated by the superheated water vapor 43 while suppressing the evaporation of water from the solution mist 72. Therefore, the film can be favorably grown epitaxially.

Also in the first and second embodiments, the pressure in the flow path through which the superheated water vapor 43 flows may be lower than the atmospheric pressure, in the similar manner to the third embodiment. In this case, the temperature of the superheated water vapor 43 can be made lower than 100° C.

In each of the embodiments described above, the solvent of the solution 21 is water. As another example, a liquid other than water may be used as the solvent. In such a case, the solution mist can be heated by a superheated vapor, which is made of the same material as the solvent.

In each of the embodiments described above, the gallium oxide film is epitaxially grown on the upper surface of the substrate. As another example, other films may be epitaxially grown. In addition, a film may be grown by a growth method other than the epitaxial growth.

The susceptor 16 of each of the embodiments is an example of a stage. The mist generation reservoir 20 of each of the embodiments is an example of a mist supply source. The superheated water vapor generator 80 of each of the embodiments is an example of a superheated vapor supply source. The superheated water vapor supply path 42, the solution mist supply path 24, and the mixing flow path 45 of each of the embodiments are examples of a delivery device. The solution mist supply path 24 of each of the embodiments is an example of a first flow path. The superheated water vapor supply path 42 of each of the embodiments is an example of a second flow path.

Although the embodiments have been described in detail above, these are merely examples and do not limit the scope of the present disclosure. The techniques described in the present disclosure include various modifications and modifications of the specific examples illustrated above. The technical elements described in the present disclosure or the drawings exhibit technical usefulness alone or in various combinations, and are not limited to the combinations described in the present disclosure at the time of filing. In addition, the techniques illustrated in the present specification or drawings achieve multiple objectives at the same time, and achieving one of the objectives itself has technical usefulness.

What is claimed is:

1. A film formation apparatus comprising:
a stage configured to allow a substrate to be mounted thereon;
a heater configured to heat the substrate;
a mist supply source configured to supply mist of a solution that comprises solvent and a film material dissolved in the solvent;
a superheated vapor supply source configured to supply a superheated vapor of a same material as the solvent; and
a delivery device configured to deliver the mist and the superheated vapor toward a surface of the substrate to grow a film containing the film material on the surface of the substrate.

2. The film formation apparatus according to claim 1, wherein
the film is epitaxially grown on the surface of the substrate.

3. The film formation apparatus according to claim 1, wherein
the solvent is H₂O, and
the superheated vapor is a superheated water vapor.

4. The film formation apparatus according to claim 3, wherein
the superheated vapor is provided to satisfy a relation of T<530G^{-0.15} at a confluence position where the superheated vapor and the mist are merged, in which T represents a temperature of the superheated water vapor at the confluence position, and G represents a mass velocity of the superheated water vapor at the confluence position.

5. The film formation apparatus according to claim 3, wherein
a temperature of the superheated water vapor is lower than 175 degrees Celsius.

6. The film formation apparatus according to claim 3, wherein
a temperature of the superheated water vapor is lower than 150 degrees Celsius.

7. The film formation apparatus according to claim 3, wherein
a pressure in a flow path through which the superheated water vapor flows is lower than an atmospheric pressure, and
a temperature of the superheated water vapor is lower than 100 degrees Celsius.

8. The film formation apparatus according to claim 1, wherein
the delivery device includes a mixing flow path that allows a mixture of the mist and the superheated vapor to flow, and
the mixture of the mist and the superheated vapor is delivered to the surface of the substrate through the mixing flow path.

9. The film formation apparatus according to claim 1, wherein
the delivery device includes a first flow path and a second flow path provided separately from the first flow path,
the first flow path is configured to deliver the mist toward the surface of the substrate, and
the second flow path is configured to deliver the superheated vapor toward the surface of the substrate.

10. The film formation apparatus according to claim 1, wherein
the superheated vapor supply source is configured to generate the superheated vapor by heating a liquid material made of the same material as the solvent to a first temperature lower than the boiling point of the liquid material, and then lowering the boiling point of the liquid material to a temperature lower than the first temperature by reducing pressure of the liquid material.

11. A method for manufacturing a semiconductor device using a film formation apparatus, the film formation apparatus includes:
a stage configured to allow a substrate to be mounted thereon,
a heater configured to heat the substrate,
a mist supply source configured to supply mist of a solution that comprises solvent and a film material dissolved in the solvent,
a superheated vapor supply source configured to supply a superheated vapor made of a same material as the solvent, and
a delivery device configured to deliver the mist and the superheated vapor,
the method comprising:
delivering the mist and the superheated vapor from the delivery device toward a surface of the substrate to grow a film containing the film material on a surface of the substrate.
